(19) United States
(12) Patent Application Publication
(10) Pub. No.: US 2025/0183672 A1
(43) Pub. Date: Jun. 5, 2025

(54) ENERGY STORAGE SYSTEMS SUITABLE FOR STATIONARY AND PORTABLE POWER APPLICATIONS

(71) Applicant: Ranjan Kumar Gupta, Bothell, WA (US)

(72) Inventor: Ranjan Kumar Gupta, Bothell, WA (US)

(21) Appl. No.: 19/035,738

(22) Filed: Jan. 23, 2025

Related U.S. Application Data
(63) Continuation of application No. 18/196,293, filed on May 11, 2023, now abandoned.
(60) Provisional application No. 63/347,072, filed on May 31, 2022.

(51) Int. Cl. H02J 4/00; H01M 10/42; H01M 10/613; H01M 10/6554; H01M 10/6556; H01M 10/659; H01M 50/204; H01M 50/258; H01M 50/296; H05K 7/20

(52) U.S. Cl. CPC H02J 4/00; H01M 10/425; H01M 10/613; H01M 10/6554; H01M 10/6556; H01M 10/659; H01M 50/204; H01M 50/258; H01M 50/296; H01M 2220/10; H01M 2220/30; H05K 7/20936

(57) ABSTRACT

Described herein are systems for energy storage leveraging various advances in power electronics so that the systems are suitable for stationary and portable power applications. In some embodiments, a system includes a universal bus and universal battery modules connected to the universal bus, in which each module includes battery cells, a power electronics transformer converter (PETC) system, and a direct expansion (DX) based phase-change cooling system to reduce heat produced by the modules to provide a system that is suitable for stationary and portable power applications.

### CROSS-REFERENCE TO RELATED APPLICATIONS

This application is a continuation of application Ser. No. 18/196,293 filed on May 11, 2023, the complete disclosure of which is incorporated herein by reference, and claims the benefit of priority to provisional U.S. Patent Application No. 63/347,072, filed on May 31, 2022, titled “ENERGY STORAGE SYSTEMS SUITABLE FOR STATIONARY AND PORTABLE POWER APPLICATIONS”, which is hereby incorporated by reference.

### TECHNICAL FIELD

The present disclosure relates to energy storage systems for stationery and portable power applications.

### BACKGROUND

A lithium-ion battery is a type of rechargeable battery which uses the reversible reduction of lithium ions to store energy. The anode of a lithium-ion cell is typically graphite made from carbon. The cathode is typically a metal oxide. The electrolyte is typically a lithium salt in an organic solvent. It is the predominant battery type used in portable power applications. It can also be used for grid-scale energy storage. Compared to other rechargeable battery technologies, Li-ion batteries have high energy densities and low self-discharge.

### SUMMARY

Described herein are novel energy storage systems for stationary and portable power applications. For example, described herein are systems for energy storage leveraging various advances in power electronics so that the systems are suitable for stationary and portable power applications. In some embodiments, a system includes a universal bus and universal battery modules connected to the universal bus, in which each module includes battery cells, a power electronics transformer converter (PETC) system, and a direct expansion (DX) based phase-change cooling system to reduce heat produced by the modules to provide a system that is suitable for stationary and portable power applications.

These and other important aspects of the invention are described more fully in the detailed description below. The invention is not limited to the particular assemblies, apparatuses, methods and systems described herein. Other embodiments can be used and changes to the described embodiments can be made without departing from the scope of the claims that follow the detailed description.

### BRIEF DESCRIPTION OF THE DRAWINGS

The present disclosure will be understood more fully from the detailed description given below and from the accompanying drawings of various embodiments of the disclosure.

FIG. 1 illustrates a prior art for battery energy storage system (BESS) based on centralized architecture.

FIG. 2 illustrates an implementation of BESS based on universal battery modules and universal bus for interfacing to utility ac power system, in accordance with some embodiments of the present disclosure.

FIG. 3 illustrates an implementation of BESS based on universal battery modules and universal bus for interfacing to DC generator or load, in accordance with some embodiments of the present disclosure.

FIG. 4 illustrates an implementation of BESS based on universal battery modules and universal bus for interfacing to AC or DC power system, in accordance with some embodiments of the present disclosure.

FIG. 5 illustrates an implementation of PETC system, in accordance with some embodiments of the present disclosure.

FIG. 6 illustrates an implementation of PETCM, in accordance with some embodiments of the present disclosure.

FIG. 7 illustrates another implementation of PETCM, in accordance with some embodiments of the present disclosure.

FIG. 8 illustrates more details of power stage 1 of FIG. 7, in accordance with some embodiments of the present disclosure.

FIG. 9 illustrates more details of power stage 2 of FIG. 7, in accordance with some embodiments of the present disclosure.

FIG. 10 illustrates implementation of universal battery module, in accordance with some embodiments of the present disclosure.

FIG. 11 illustrates DX cooling system operation, in accordance with some embodiments of the present disclosure.

FIG. 12 illustrates more details of universal battery module including DX cooling system, in accordance with some embodiments of the present disclosure.

FIG. 13 illustrates implementation of universal battery rack, in accordance with some embodiments of the present disclosure.

### DETAILED DESCRIPTION OF EXAMPLE EMBODIMENTS

Details of example embodiments of the invention are described in the following detailed description with reference to the drawings. Although the detailed description provides reference to example embodiments, it is to be understood that the invention disclosed herein is not limited to such example embodiments. But to the contrary, the invention disclosed herein includes numerous alternatives, modifications and equivalents as will become apparent from consideration of the following detailed description and other parts of this disclosure.

Described herein are novel energy storage systems for stationary and portable power applications. For example, described herein are systems for energy storage leveraging various advances in power electronics so that the systems are suitable for stationary and portable power applications. In some embodiments, a system includes a universal bus and universal battery modules connected to the universal bus, in which each module includes battery cells, a power electronics transformer converter (PETC) system, and a direct expansion (DX) based phase-change cooling system to reduce heat produced by the modules to provide a system that is suitable for stationary and portable power applications.

Several methods exist to build a Li-ion battery energy storage system (BESS) by combining thousands of individual Li-ion battery cells for mobility (e.g., electric vehicle) and stationary applications (e.g., pairing with solar for residential, commercial, or utility applications). The centralized system architecture to combine 1000s of Li-ion cells to realize a certain power and energy rating is typical to methods, which is highly sensitive to a cell failure elaborated as follows. The battery cell failure and subsequent thermal runaway is a safety concern reported in fire incidents.

A BESS is built using the centralized architecture. For example, hundreds of 2170 cylindrical cells (3.7V, 2.5 Ah) are connected in parallel and then in series to achieve a higher energy rating battery-unit pack, e.g., 48V, 6 kWh. Several battery-unit-packs are then connected in series to build a battery-module with a rating e.g., 400V, 80 kWh. Several of these battery modules are then connected in series or parallel to achieve the rating of 100s of kWh or a few MWh battery-rack. The process of combining 1000s of cells to realize a battery-rack requires hundreds of disconnects, fuses, and battery management systems (BMSs) to contain the impact of a single cell failure. The battery-rack is then configured to be coupled to a centralized DC/DC or DC/AC inverters with respective utility transformers to interface to the utility power system for charging and discharging. Several of these resulting battery racks plus DC/AC and transformers can be connected in parallel to the electrical utility feeder to scale power and energy rating; these components are collectively referred to as battery energy storage systems (BESS). The battery-racks generate heat under normal operations, and cells are sensitive to operating temperature. A dedicated centralized active cooling system is used to channel coolant liquid to battery-modules to maintain the cell temperatures within a controlled range.

One example problem of the centralized architecture can be that when cells (or battery-unit-packs, or battery modules, etc.) are paralleled, their voltage must be matched to avoid an uncontrollable short-circuit-current because they are electrically parallel and cell resistance is too low. The short circuit current (e.g., in the range of 10s of kilo-amps) rapidly results in thermal runaway if one of those hundreds of fuses or disconnect switches malfunctions. Also, concerning the overall system's performance, an individual cell in the system is the weakest link. Under normal operational conditions, one of the cell's inferior qualities (e.g., due to manufacturing defects) limits the pack energy rating. In the event of a cell malfunctioning, under regular isolation operation, the array of batteries may require deactivation.

Another example problem is the temperature gradient developed across the battery modules, which causes each cell to operate under slightly different temperatures, creating long-term voltage mismatch, resulting in a reduced performance rating of the entire system. The central coolant flow over a long coolant hose causes a significant pressure drop (in addition to the temperature gradient in modules), limiting the heat transfer capability of the overall system regardless of the coolant pump power rating. The other problems include leakage, which has been known to cause fire incidents. An example result is that the centralized cooling system is ineffective in extracting an amount of heat to reverse the course or stop abnormal thermal management events ahead of the thermal runaway event that is uncontrollable when it happens.

Another example problem of a centralized architecture is the lower energy density, which increases the complexity and reduces the economic value proposition of portability of BESS to another location to support other use cases. The weight and volume of everything else other than the battery cells (e.g., the overhead) is over 50% in many cases due to the presence of the following disaggregated subsystems in a centralized architecture: intermediate DC bus and the management of the resulting DC collection system, required DC cabling, switchgear & protection, DC/AC inverters, centralized cooling, auxiliary power supplies, and cabling to connect subsystems.

This disclosure presents examples of systems and methods for providing an energy storage system suitable for stationary and portable power applications while providing enhanced performance and lower risk of fire hazards. An example approach involves taking a block of cells without any paralleling of cells inside the block, providing a power electronics transformer converter for galvanically isolating the blocks, and including a distributed phase-change-based thermal management system for enhanced thermal management to contain abnormal events that lead to thermal runaway. This approach provides a modular building blocks of Li-ion cells and electronics and thermal management, which can be multiplied to increase output (such as it can be paralleled). Such features are enabled because the battery has been provided with a power electronics transformer interface, and the collocated and distributed thermal management offers an increase in the ability to contain factors that cause thermal runaway. Although Li-ion cells are discussed herein, it is understood that the technologies disclosed herein are applicable to any battery cell technology. For example, some embodiments can use or be used with sodium ion cells.

The system describes techniques of implementing a universal power electronics transformer converter connected to a universal bus to directly connect to the utility power system and AC loads without an additional centralized DC/AC or AC/DC power converter and without an intermediate DC bus. The methods describe a unique approach to configure the universal bus to an AC or a DC bus for interfacing with an AC or DC generator or loads without requiring a centralized AC/DC or DC/DC converter. The methods further describe an approach to containing a fault battery module (and in some examples, while enabling other modules to work usually) and combining forces of several distributed thermal management systems to rapidly slow down factors (e.g., in the faulty modules) that could lead to thermal runaway.

Due to the integrated and modular electrical and thermal management systems, the failure of one universal module—whether electrical or thermal—does not impact the other modules—increasing overall system availability.

Another example advantage of the proposed approach is that different ages of cells or other cell chemistry (e.g., NMC, LFP, Solid State, etc.) with different overall DC voltages can be connected in parallel since there is no intermediate DC bus, no centralized power converter, and the battery modules are galvanically isolated. The universal power electronics transformer converter provides a standard interface to ac system (such as a 480V three-phase utility ac system).

The technologies described herein further include the integration of universal modules to form a rack and then BESS to maximize the energy density. Further, arrangements are described to reconfigure the output terminals as AC or DC terminals without additional cables or connections. These aspects are particularly beneficial for portable power applications.

Examples herein describe cells as a fundamental building block of the energy storage system. In various implementations, any electrochemical cell can be used. For example, this includes, but is not limited to lithium-ion cells having a prismatic form factor.

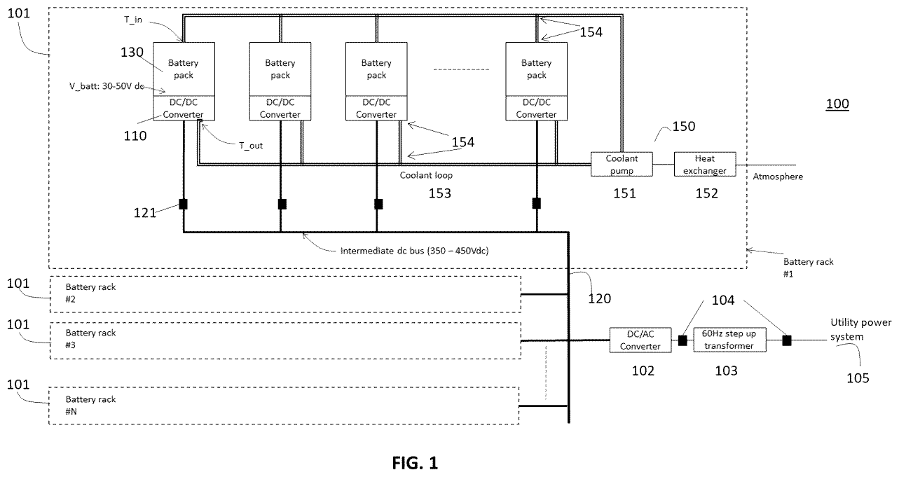

Various approaches have been attempted to implement a BESS to mitigate the disadvantages of a centralized system. FIG. 1 shows one such system to realize a BESS 100 (e.g., sec U.S. Pat. No. 10,424,923 B2) which includes several battery rack 101. Several battery rack 101 are connected in parallel to the intermediate DC bus 120 using DC protection system 121. A central DC/AC inverter 102 converts the DC power to AC power; AC protection system 104 and step-up transformer 103 are typically used to connect to the utility power system 105. The distributed DC/DC converter 110 connected between the intermediate DC bus 120 and the battery pack 130 provides galvanic isolation among the battery packs. The galvanic isolation eliminates the chance of any short circuit between the battery cells of battery pack 130 and the cells of another battery pack 130, despite any voltage mismatch, because the battery packs are not in direct parallel anymore. However, within each battery pack 130, for example, several 3.7V 2.5 Ah cells (not shown in FIG. 1) are still connected in parallel and then in series to achieve for example 6 kWh battery pack rating. Therefore, a mismatch in cell characteristics or a single cell failure combined with a malfunctioning of a fuse can still cause a short circuit inside the battery pack, although limited to that battery pack. Therefore, while such a system eliminates paralleling at high voltage, it does not eliminate the electrical paralleling problem fully because the paralleling at a low voltage within the battery pack still exists.

Additionally, prior systems rely on a centralized cooling system 150, including components such as coolant pump 151, heat exchanger 152, long coolant loop 153 to DC/DC converters 110 and battery pack 130 interconnected by long coolant loop 153 using joints and interconnection 154. The centralized cooling system 150 creates a temperature gradient across the cells inside the battery packs, causing cells to operate under slightly different temperatures, creating long-term voltage mismatch, thereby reducing the performance rating of the entire system. The central coolant flow over a long coolant hose (loop) causes a significant pressure drop (in addition to the temperature gradient in packs), limiting the heat transfer capability of the overall system regardless of the coolant pump 151 power rating. As a result, the centralized cooling system is sufficiently designed to extract heat from the battery cells in normal and overloaded operating conditions. However, it is insufficient and ineffective to remove an amount of heat to reverse the course or stop abnormal thermal management events ahead of a thermal runaway event in any battery pack 130. For example, suppose a battery short circuit (or any other malfunction leading to excessive heat generation) inside a battery pack 130 is not interrupted, then in minutes, the cell temperature rises to well above 100 C (relative to say 30 C normal operating temperature), followed by rising to well above 500 C in a matter of subsequent seconds. This transition is considered the point of no return, after which the cells undergo thermal runaway and fire. The cause of excessive heat generation sometimes is unavoidable-it can be from an electrical abuse (battery cycling over ratings), or a mechanical abuse (excessive shock and vibration), or a thermal abuse (poor heat extraction system), or a manufacturing defect that can cause an internal short circuit inside the cells, for example. The centralized cooling system 150 should be able to stop or reverse the course of events (temperature increase from 30 C to 100 C) before thermal runaway (increase from 100 C to >500 C), which may require a short-term ultra-boost in cooling capacity. Unfortunately, the centralized cooling system 150 cannot provide it because of long coolant loop 153 and joints and interconnection 154, causing an increased likelihood of leaks and rupture (among other deficiencies of the centralized cooling system). These limitations prohibit implementing a high-pressure system to increase the heat transfer capability.

Also, BESS 100 require an intermediate DC bus 120, which means central DC/AC inverter 102 is necessary to interface to the utility power system 105. The intermediate DC bus 120 requires an extra set of DC protection systems 121, such as DC cables, fuses, disconnects, etc., rated for high voltage, such as 400V to 1000V. Such high voltage DC comes with the additional risk of managing a high short circuit current resulting from a potential fault on the intermediate DC bus 120. In such an event, while DC/DC converters 110 can isolate the battery pack 130 from the bus, the central DC/AC inverter 102 (it being bidirectional power flow capable) can source 10s of kilo-amps of current from the utility power system 105, creating another source of fire hazard. Such results may depend on DC protection system 121 and careful choice of AC protection system 104 and tailormade for each system based on the BESS 100 rating. So, due to the requirement of additional bulky components, another limitation of the centralized architecture is the lower energy density, which increases the complexity and reduces the economic value proposition of portability of BESS 100 to another location to support other use cases. The weight and volume of components other than the battery cells (the overhead) of battery pack 130 is over 50% in many cases due to the presence of the following disaggregated subsystems in the centralized architecture: intermediate DC bus 120 and the management of the resulting DC collection system, required DC cabling, switchgear & protection, central DC/AC inverters 102, centralized cooling system 150, auxiliary power supplies, and cabling to connect subsystems (not shown in FIG. 1).

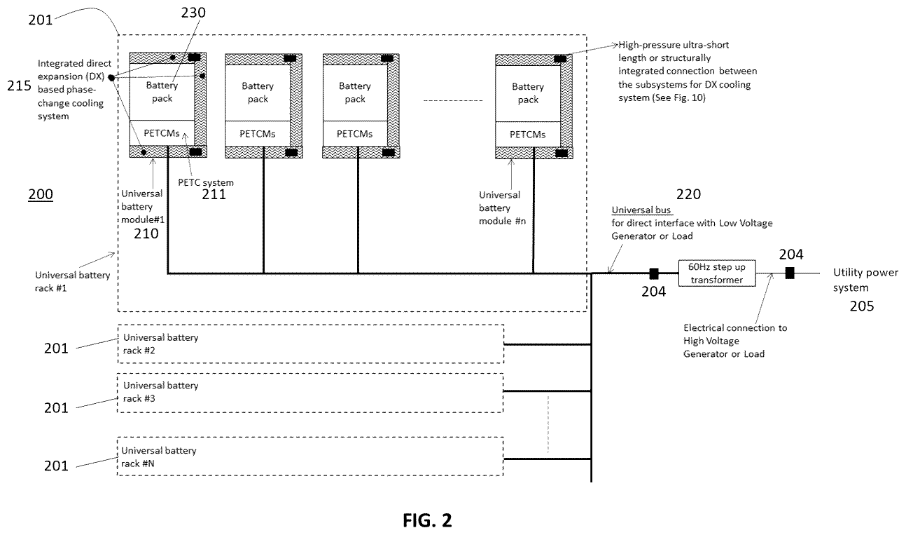

FIG. 2 describes an example implementation for a BESS 200 to eliminate the shortcomings of a centralized architecture. Universal battery module 210, as shown, can be connected in parallel to scale to any power and energy ratings. In such an implementation, there is no intermediate DC bus 120, and there is no centralized DC/AC inverter 102 to connect to utility power system 205. The universal bus 220 is an AC bus in an example implementation when the BESS 200 is connected utility power system 205 including an AC generator or load.

The universal battery module 210 contains a power electronics transformer converter system 211 (or PETC system 211) with multiple input and output terminals. The input terminals are galvanically isolated from one another. They are also galvanically isolated from the output terminals. The galvanic isolation is accomplished with several high-frequency transformers (operating in concert with power electronics switches at a frequency order of magnitude higher than the standard 60 Hz utility transformer) inside the PETC system. In an example implementation, PETC is configured such that it has 12 input terminals for 12 individual serial-only connected battery cells; further, it has three output terminals. The 12 inputs terminals are connected to strings of series only cells (e.g., 12 strings of series only cells), each string having 12-14 cells of 3.7V 100 Ah rating, to achieve a corresponding number of sets of 30-60V 4-6 kWh each battery cell strings-together referred to as a battery pack 230 as shown in FIG. 2. The total rating of each of the battery pack 230 in this example is then 30-60V, 48-72 kWh. The output terminal of the PETC system 211 of universal battery module 210 is a three-phase AC in this example. Therefore, universal bus 220 is a three phase AC bus in this example. Due to the serial-only connection of the battery cells inside the battery pack 230 at the input terminals of the PETC system 211, the chances of an electrical short circuit between two cells is reduced significantly.

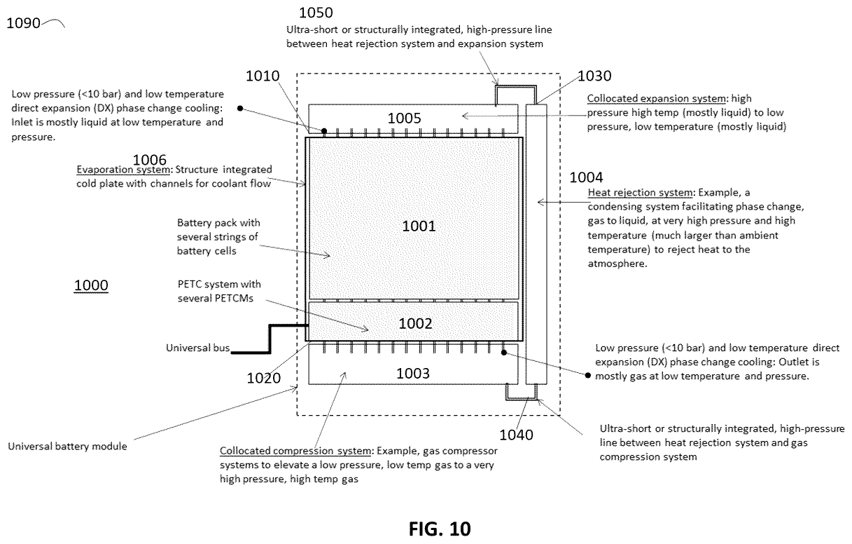

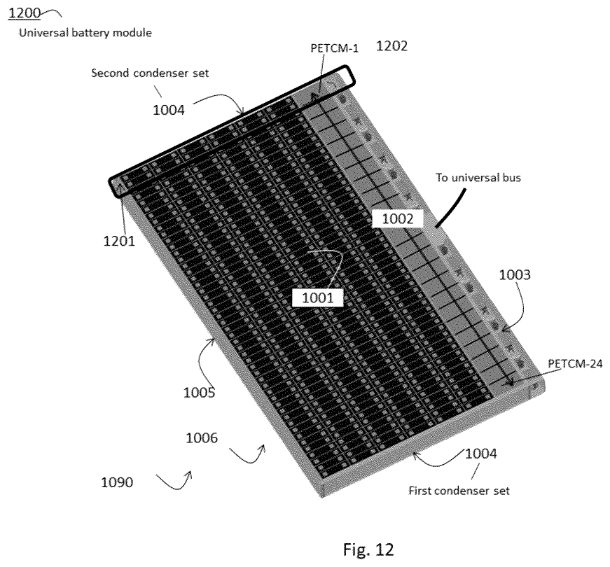

In an example implementation, for cooling the battery cells and PETC system 211, the universal battery module 210 includes a direct expansion (DX) based phase-change cooling system, referred to as DX cooling system 215 that is installed in the vicinity of the battery pack and PETC system. In another example implementation (See FIG. 12) it is integrated with the mechanical structure of the frame that holds the battery pack 230 and PETC system 211. Such an integrated modular DX cooling system (such as system 215) inside the universal battery module 210 results in an ultra-short high-pressure coolant pipe length, which enables ultra-high pressure high-temperature refrigeration cycle (See FIG. 10 and associated description). In this implementation of universal battery module 210, the shorter coolant pipe length from the condenser to expansion and from evaporation to condenser system allows the cooling system pressure up to 20-30× higher (e.g., up to 30 bars) than the state of the art water-glycol based liquid cooling. This can result in the coolant phase change provision from liquid to gas (as it passes through the battery pack 230 and PETC system 211) and subsequent heat rejection to the atmosphere at high pressure and temperature (as the coolant passes through the condenser and compressor system) accomplishes a high heat transfer capacity. Note that such high-pressure operation which enables phase-change and enhanced cooling system capacity is impractical in prior-art (FIG. 1) due to long coolant loop 153 and joints and interconnection 154 that are necessary to transport liquid coolant from the centralized cooling system 150. In the proposed BESS 200, the cooling system is distributed and implemented inside each of the BESS 200, resulting in mechanical and thermal conditions to implement the distributed DX cooling system 215.

Such a boost in cooling can not only be utilized to drive the battery inside the battery pack 230 harder, but it can also be used to create a below-freezing temperature inside the selected battery pack 230 to contain events that cause thermal runaways. Further details of the PETC system 211 and DX cooling system 215 are described herein.

Such systems reduce the chances of DC faults in the battery pack 230 due to the absence of parallel cells. The system does not have any intermediate DC bus 120 and central DC/AC inverter 102—therefore a high-voltage de fault does not exist. The DX cooling system 215 and its integration with the battery pack 230 and PETC system 211 increase the cooling capacity. It also enables short-term boost of cooling capacity, which can contain causes that create thermal runaway—thereby reducing the chances of thermal runaway events in the BESS 200.

The system is modular—including the following modular components: battery, electrical, thermal, and mechanical. Several of the universal battery module 210 can be connected parallel to create a rack 201. Several of the rack 201 can be connected in parallel to increase the power and energy rating, which can directly interface with an AC load or generator of the utility power system 205 using AC protection system 204. A step-up transformer 203 is used to connect to a higher voltage power system. Several of these racks groups can be connected to their respective step-up transformer to scale to a selected power and energy rating.

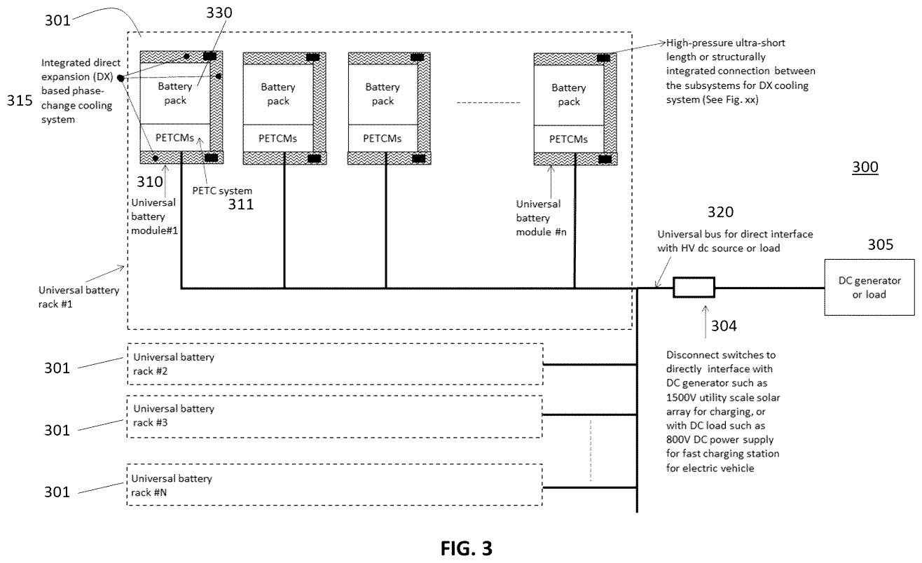

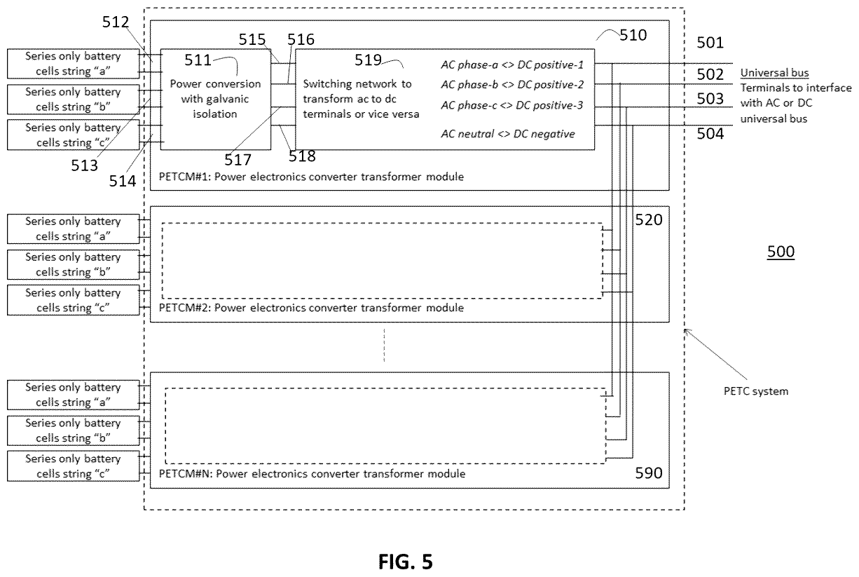

FIG. 3 shows another example implementation of the BESS 300 to interface directly with a high voltage DC generator or load 305. The PETC system 311 is configured to have several DC/DC converters (not shown in FIG. 3, the concept is described in detail in FIG. 5 through 9) in this implementation to charge for example from solar array directly (e.g., from a 1500V array) or directly deliver DC power supply for charging infrastructure for electric vehicles (e.g., at 800V dc). Such a DC-only implementation is particularly beneficial for a portable BESS system. The BESS is charged from a solar farm at one location and delivers power for EV charging at another location. The universal bus 320 in this implementation is a DC bus to which multiple universal module 310 are connected in parallel. The universal module 310 in this implementation includes similar components as follows: PETC system 311, battery pack 330 and DX cooling system 315. Several universal module 310 forms a universal battery rack 301 as shown. Several universal battery rack 301 are connected in parallel to couple to DC generator or load 305 using a DC protection system 304.

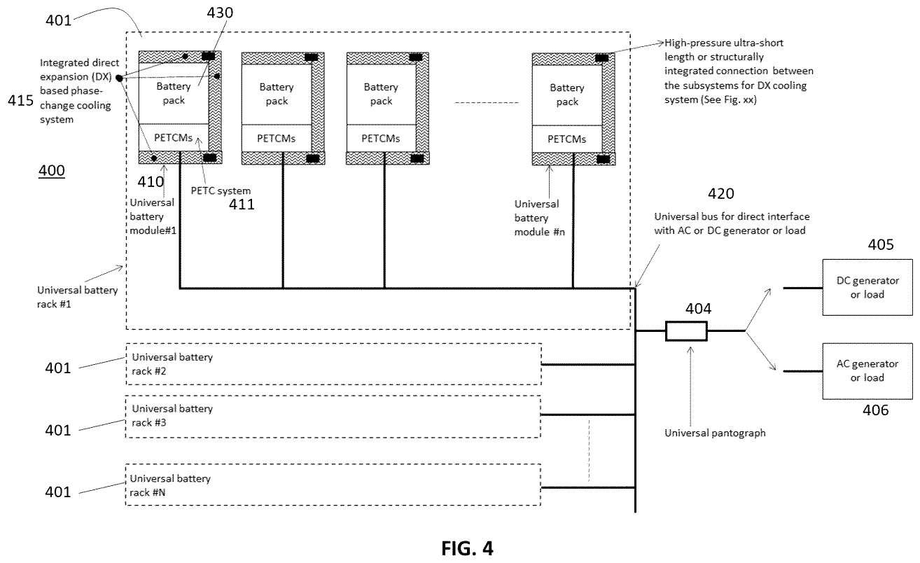

FIG. 4 shows another example implementation of the BESS 400 to interface directly with any type of DC power system 405 or AC power system 406. In an example, the universal pantograph 404 is designed to engage or disengage automatically (like in electrical locomotives or buses) to DC power system 405 or AC power system 406. The PETC system 411 is configured to include several universal PETCMs converters (not shown in FIG. 4, the concept is described in detail in FIG. 5 through 9) in this implementation in that PETC system 411 output terminals can be a three-phase AC or high voltage DC for both charging and discharging the battery cells. Therefore, the universal bus 420 in this example is configurable to be an AC or DC bus without requiring additional cabling for AC or DC. The output terminals of universal battery module 410 and the universal bus 420 are AC at one time and DC at another time—reconfigurable from a controls switch assembly (not shown in FIG. 4, the concept is described in detail in FIG. 5 through 9). The universal battery module 410 in this implementation includes similar components as follows: PETC system 411, battery pack 430 and DX cooling system 415. Several universal battery module 410 forms a universal battery rack 401 as shown. Several universal battery rack 401 are connected in parallel to couple to DC power system 405 or AC power system 406.

Such a universal implementation is particularly beneficial for a portable BESS system in which the BESS is charged from an AC (or DC) generating source at one location and delivers power to a DC (or AC) load at another location.

FIG. 5 shows an example implementation of the PETC system 500 which includes several power electronics transformer converter modules (PETCMs); As an example, nine PETCMs 510 to 590 are shown in FIG. 5. Each PETCM has power electronics and high-frequency transformers, together shown as power conversion with galvanic isolation 511, to provide galvanic isolation among three input terminals pair described as first pair 512, second pair 513 and third pair 514. (for example the first pair 512 is a DC terminal with positive and negative pair of terminals), between the three input terminals pair and four outputs terminals described as first terminal 515, second terminal 516, third terminal 517, fourth terminal 518). The power conversion with galvanic isolation 511 performs charging and discharging of battery cells connected to three input terminals pair described as first pair 512, second pair 513 and third pair 514. The PETCM 510 also contains an integrated switching network 519 that converts the four outputs terminals described as first terminal 515, second terminal 516, third terminal 517, fourth terminal 518 to an AC output or DC output terminal described as first output terminal 501, second output terminal 502, third output terminal 503, fourth output terminal 504 depending on the status of the switch inside the integrated switching network 519. The status of the switches inside the integrated switching network 519 is controlled to configure the output terminal (described as first output terminal 501, second output terminal 502, third output terminal 503, fourth output terminal 504) as DC or AC. Many such PETCMs 510 through 590 (nine of them as an example) are connected in parallel at the output terminals (described as first output terminal 501, second output terminal 502, third output terminal 503, fourth output terminal 504) of the universal bus. At the input terminals pair (described as first pair 512, second pair 513 and third pair 514) of the PETCM 510, the first pair 512, second pair 513 and third pair 514 are galvanically isolated from each other, they accept strings of battery cells—each, for example, 30-60V, 4-6 kWh. In an example, four output terminals (described as first terminal 515, second terminal 516, third terminal 517, fourth terminal 518) are shown in FIG. 5, which are programmable using the integrated switching network 519 to be a three-phase AC (three terminal) plus a floating neutral (fourth terminal) output terminals (described as first output terminal 501, second output terminal 502, third output terminal 503, fourth output terminal 504). In another implementation, these four terminals (described as first terminal 515, second terminal 516, third terminal 517, fourth terminal 518) are configurable to three positive DC terminals and one DC negative terminal, or three negative DC terminals and one positive DC terminal, etc., as the output terminals (described as first output terminal 501, second output terminal 502, third output terminal 503, fourth output terminal 504). For a single-phase AC output interface, the output terminals (described as first terminal 515, second terminal 516, third terminal 517, fourth terminal 518) can be selectively programmed by using the integrated switching network 519 to act as an AC mains phase and AC returns phase.

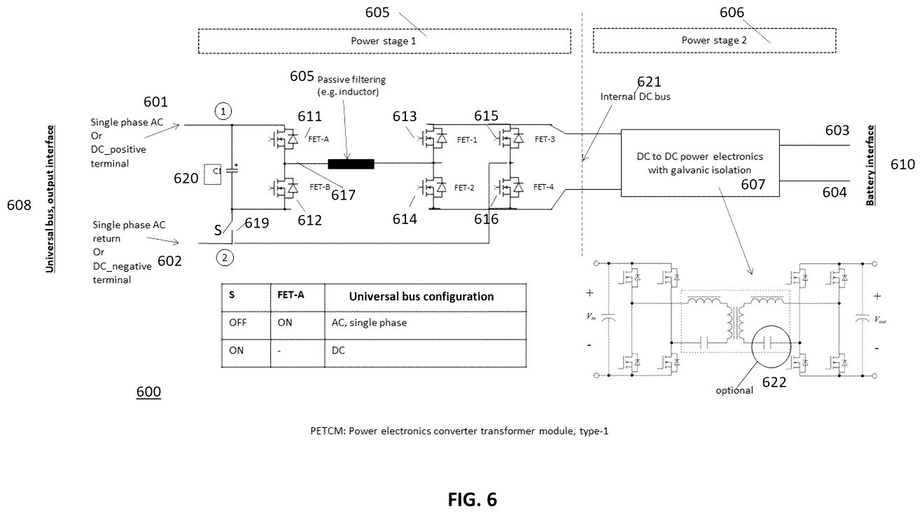

FIG. 6 shows an example of the implementation of PETCM 600 for a single-phase AC output interface or DC output interface to the universal bus 608 with terminal 601 and second terminal 602. The integrated switching network in this example is a switch S 619 as shown in FIG. 6. The table presents the universal bus first terminal 601, second terminal 602 configuration by selecting the status of switch S 619.

When switch S 619 is OFF (or OPEN)—the universal bus first terminal 601, second terminal 602 are AC single-phase. With switch, S 619=OFF and the FET-A 611 permanently on in an example implementation, the FET-1 613, FET-2 614, FET-3 615, and FET-4 616 in a power stage-1 605 form an H-bridge circuit topology to function as an AC to DC bidirectional converter. The universal bus first terminal 601 is directly connected to the mid-point 617 of the passive filter 618, whereas the capacitor C 620 and FET-B 612 is electrically out of the circuit because FET-A 611 is ON. The DC side is an internal DC bus 621 in this AC to DC bidirectional converter. This internal DC bus 621 connects power stage-1 605 and power stage-2 606, and the power-stage-2 606 is a DC/DC isolated power converter 607 to interface with a string of battery cells 610. The DC/DC isolated power converter 607 of power stage-2 606 is a bi-directional DC/DC converter (as shown in an example implementation) with a high-frequency transformer. This circuit provides galvanic isolation of battery first terminal 603 and battery second terminal 604 from the rest of the circuit components such as DC bus 621 and universal bus first terminal 601, second terminal 602, and voltage matching in concert with the AC/DC bidirectional power stage-1 605 controls for battery cells 610 (with battery first terminal 603 and battery second terminal 604) charging-discharging.

When S 619 is ON (or CLOSED)-the universal bus first terminal 601, second terminal 602 are DC. With S=ON, the FET-A 611, FET-B 612, FET-1 613, FET-2 614 in power stage-1 605 forms a DC to DC buck-boost converter, for example, by permanently turning the FET-4 616 ON. One side of the DC is the output terminals to connect with the universal bus 608, whereas the other side of the DC is the internal DC bus 621. The power stage-2 606 is the same DC/DC isolated power converter 607 to interface with a string of battery 610.

The implementation of transition from a DC to AC output terminals at universal bus first terminal 601, second terminal 602 and vice-versa includes, for example, discharging the capacitor C 620 as shown in FIG. 6 to a pre-defined level using switch S 619, FET-A 611, FET-1 613 and FET-3 615. In an example implementation, these devices switch S 619, FET-A 611, FET-1 613 and FET-3 615 are turned on to create a discharge loop for capacitor C 620 using the resistor of the passive filter 618. In another example implementation of the hardware for power stage-2 606, the resonant capacitor 622 on the secondary side of high frequency transformer, as shown, is not installed since two power stages power stage-1 605 power stage-2 606 can control the electrical parameters for bi-directional power flow.

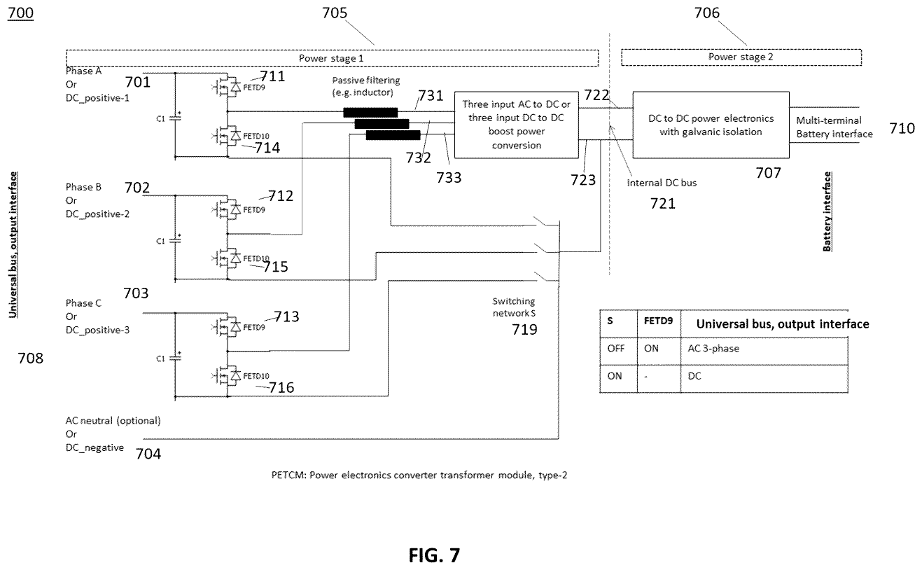

FIG. 7 shows an example of the implementation of PETCM 700 for a three-phase AC output interface or multiple-DC output interface with the universal bus output interface 708 with four terminals: first terminal 701, second terminal 702, third terminal 703 and fourth terminal 704. The integrated switching network S 719 is a group of three switches configured as shown in FIG. 7 as an example implementation. The table presents the universal bus output interface 708 configuration by selecting the status of switches inside the integrated switching network S 719.

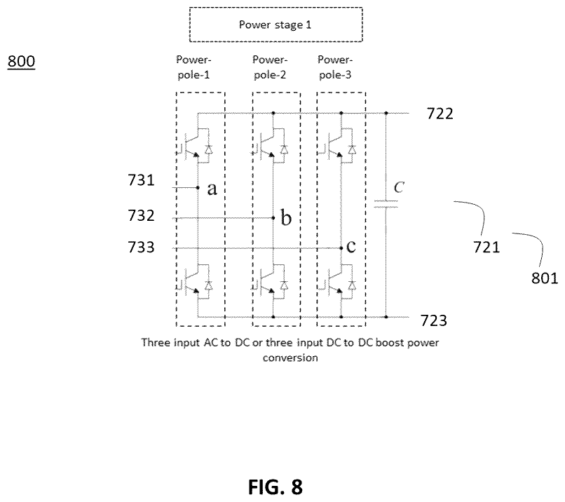

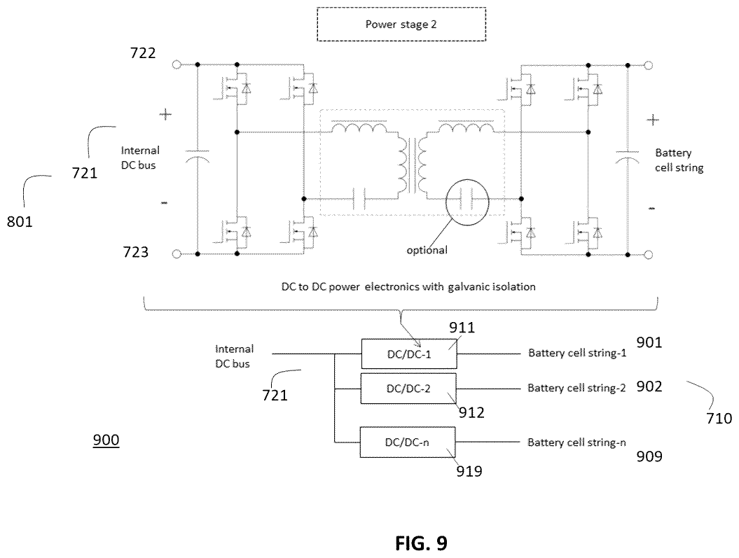

In an example implementation, when all switches of integrated switching network S 719 is OFF (or OPEN)—the output terminals the universal bus output interface 708 with four terminals: first terminal 701, second terminal 702, third terminal 703 and fourth terminal 704 are three-phase AC when all switches of integrated switching network S 719 are OFF and three FETD9 switches, with first FETD9 711, second FETD9 712 and third FETD9 713, are ON, the three terminals of the universal bus output interface 708: first terminal 701, second terminal 702, third terminal 703, together with AC to DC power converter in power stage-1 705 forms a standard three-phase AC to DC bidirectional converter 800 (as shown in FIG. 8). The DC side 801 is an internal DC bus (same as internal DC bus 721 in FIG. 7) in this three-phase AC to DC bidirectional converter 800. This internal DC bus 721 connects power stage-1 705 and power stage-2 706; the power-stage-2 706 is a DC/DC isolated power converter 707 to interface with strings of battery cells 710. The DC/DC isolated power converter 707 of power stage-2 706 contains a DC/DC transformer system 900 with multiple bi-directional DC/DC converters with high-frequency transformers as shown in FIG. 9. The DC/DC transformer system 900 includes multiple bi-directional DC/DC converters with high-frequency transformers, referred as DC transformer modules. In FIG. 9, as an example implementation, the DC/DC transformer system 900 includes nine DC/DC transformer modules, with first DC/DC transformer module 911, second DC/DC transformer module 912, and so on, and ninth DC/DC transformer module 919. In FIG. 9, as an example implementation, nine bidirectional DC/DC transformer modules provide galvanic isolation for strings of battery cells 710 including in this example implementation nine strings with first string of battery cells 901, second string of battery cells 902, and so on, to ninth string of battery cells 909. The nine DC/DC transformer modules, with first DC/DC transformer module 911, second DC/DC transformer module 912, and so on, to ninth DC/DC transformer module 919 provide galvanic isolation to first string of battery cells 901, second string of battery cells 902, and so on, to ninth string of battery cells 909 from one another, from the rest of the circuit (bus 721 and universal bus output interface 708 with four terminals: first terminal 701, second terminal 702, third terminal 703 and fourth terminal 704), and necessary voltage matching in concert with the three-phase AC/DC bidirectional power conversion in power stage-1 705 for battery charging and discharging.

When the switches inside the integrated switching network S 719 are ON (or CLOSED)—the universal bus output interface 708 with four terminals: first terminal 701, second terminal 702, third terminal 703 and fourth terminal 704 are DC. With switches inside the integrated switching network S 719 ON, the three FETD9 switches, with first FETD9 711, second FETD9 712 and third FETD9 713 and three FETD10 switches, with first FETD10 714, second FETD10 715 and third FETD10 716 along with the three power poles (first power pole 731, second power pole 732, third power pole 733) of Power stage-1 (FIG. 8) form a three-input DC to DC buck-boost converter. One side of the three-input DC are thee power poles (first power pole 731, second power pole 732, third power pole 733) to couple with the universal bus output interface 708 with four terminals: first terminal 701, second terminal 702, third terminal 703 and fourth terminal 704 (which is now DC), whereas the other side of the DC is the internal DC bus 721 with first internal DC terminal 722 and second internal DC terminal 723 in an example implementation. The power stage-2 706 is the same DC/DC isolated power conversion to interface with strings of battery cells as described in the previous paragraph.

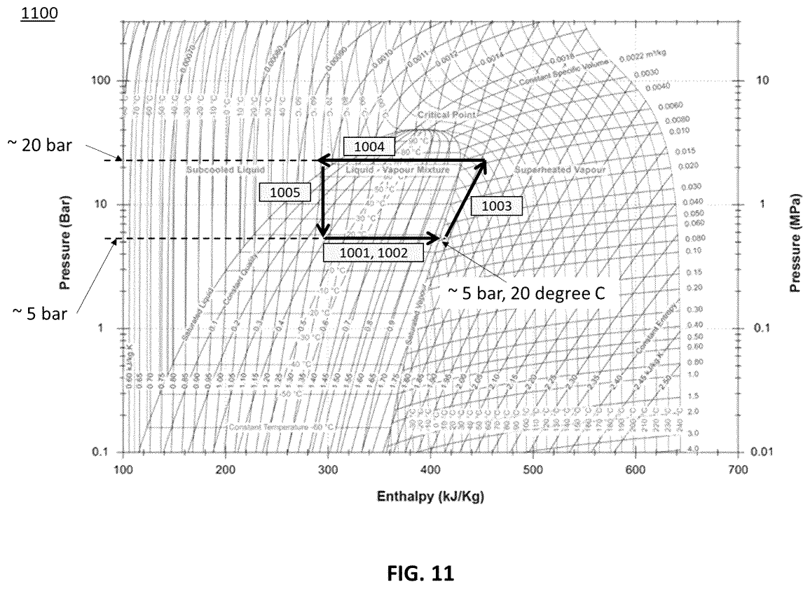

FIG. 10 shows an example implementation of the universal battery module 1000, particularly highlighting an example implementation of the direct expansion (DX) cooling system 1090 integrated with the other components of the universal battery module 1000. The DX cooling system 1090 includes an expansion system 1005, compression system 1003, condenser system 1004, and an evaporation system 1006—which is the cold plate on which the battery pack 1001 and PETC system 1002 are installed. The cold plate includes channels for coolant flow. From the output of the expansion system 1005, a liquid coolant (e.g., refrigerant R134a) at a low temperature (say 20 C) passes through the cold plate of the battery pack 1001 and PETC system 1002. The flow rate of liquid coolant, pressure, temperature, etc., are selected. The coolant changes its phase from mostly liquid at the evaporation system entry 1010 to mostly gas as it comes out at evaporation system exit 1020 of the evaporation system 1006, which for further clarity includes the cold plate coupled to the battery pack 1001 and PETC system 1002 for transferring heat (cooling or heating) to the battery pack 1001 and PETC system 1002. In one implementation, the liquid coolant absorbs heat generated from the battery pack and PETC system as it flows through the cold plate, changing the coolant phase from liquid to a gas. The resulting low pressure, low-temperature gas enters the compression system 1003, elevating the gas to a high-pressure high temperature (higher than the ambient, e.g., 70 degree C.) gas for rejecting heat to the atmosphere in the condenser system 1004. The gas changes its phase to liquid while rejecting heat in the atmosphere-the condenser output 1030 of the condenser system 1004 is a high-pressure, high-temperature liquid. The liquid then enters an expansion system 1005 that decreases the pressure, converting it to a low-pressure, low-temperature coolant, mostly liquid-which enters the battery pack and PETC system for the next cycle of heat extraction. The heat extraction cycle 1100 is shown in FIG. 11 for detailed illustration using the standard PH curves of the refrigerant coolant R134a; the compression system 1003 elevates the pressure to e.g., ˜20 bar, which is substantially higher than in the state-of-the-art glycol-based coolant pipes. The flow rate of the coolant in the DX cooling system 1090 is controlled appropriately to maintain the evaporator system 1006 temperature at the selected value in an example implementation.

In an example implementation, due to the proximity of the condenser system 1004 to the battery pack 1001 and PETC system 1002, and to the evaporation system 1006 and compression system 1003, the length of the high-pressure and high-temperature connections that carries gas and liquid is small (lower than 10 inches in an example)—reducing chances of any leaks or derating of cooling capacity. These connections are shown as high-side connection 1050 and low-side connection 1040. Such connections can be integrated in the body of the battery pack structure of the universal battery module 1200 as shown in FIG. 12. Given the proximity of the expansion system 1005 and compression system 1003 to the battery pack 1001 and PETC system 1002, the channels for the coolant can be designed (as an example implementation) to be integrated with the battery pack and PETC system's mechanical structure. In this example, such a structural integrated cold plate that includes channels for phase-changing coolant acts as an evaporator system 1006 of the DX cooling system 1090.

In the DX cooling system 1090, since the temperature gradient inside the evaporator system 1006 remains mostly flat (under the battery pack 1001, in one implementation) because the heat transfer happens due to the phase change of coolant from liquid to gas, the temperature gradient of the battery cells of the battery pack 1001 is lower than in state of the art. Therefore, in this example of the design of the universal battery module 1000, with no parallel connection of battery cells inside the battery pack 1001, combined with a minimal temperature gradient, an enhanced battery performance is achieved along with reduction of a chance of thermal runaway.

Referring to FIG. 10, in another example implementation, the compression system 1003 can be toward a first end of the battery pack 1001. The expansion system can be near a second end of the battery pack 1001 opposite of the first end. In this configuration, the coolant enters the PETC system 1002 first in mostly liquid state, and then the battery pack 1001, and exit the battery pack 1001 in mostly gas state.

In another example implementation, the universal battery module 1000 includes a central controls system (not shown in FIG. 10) that coordinates power flow among the PETCMs of the PETC system 1002. In an example implementation, the battery management system is integrated with the PETCMs of the PETC system 1002. In another example implementation, the battery management system of the pack 1001 is integrated with the central controls system inside the universal battery module 1000.

In an example implementation, as shown in FIG. 12, the arrangement of components inside the universal battery module 1200, is showing DX cooling system 1090 components-evaporation system 1006 (cold plate under the battery pack 1001 and PETC system 1002), compression system 1003, condenser system 1004, and expansion systems 1005 while also depicting the connection of battery cells to PETCMs. As an example, there are 24 strings of battery cells, each string including 12 cells; A total of 288 cells are arranged in a 48 rows and 6 columns grid. The first string of cells C1-C2- . . . -C12 1201 is connected to the one PETCM1 1202, and so on for other strings and PETCMs. The compression system 1003 and expansion systems 1005 include 8 distributed units for 8 sections of the evaporation system 1006 (cold plate under the battery pack 1001 and PETC system 1002). The compressors of the compression system 1003 and valves of the expansion system 1005 can either operate independently or in a group mode to increase the heat transfer capability of one of the eight segment (in an example implementation) of the evaporator system 1006. In one implementation, this feature is used to control the onset of thermal runaway events as described in the subsequent paragraphs. The condenser system 1004, including two sets of condensers as set-1 and set-2, is a heat rejection system for the DX cooling system 1090.

In an example implementation for containing the events that could otherwise lead to the onset of thermal runaway, the universal battery module 1000 includes a controls system for the DX cooling system 1090 and voltage, temperature sensors for the monitoring of cells, and electronic parts. The controls system estimates the cell temperature of battery cells inside the battery pack 1001 using parameters such as power flow, coolant flow, and ambient temperature and then compares it to the actual temperatures of cells from the sensors. The events causing thermal runaway could be excessive heat generation from internal cell failure due to manufacturing defects, or other types of electrical, mechanical, and thermal abuse, which cause the battery cell temperature to rise as a function of time. The battery cell undergoing the event can be referred to as the subject-cell, the section of the evaporator of the evaporation system 1006 where the subject-cell is located as a subject-cell-location, and the universal battery module 1000 in which the subject-cell is located the subject-universal-module. The subject-cell has two distinct stages of temperature rise. In the second stage, the subject-cell undergoes thermal runaway followed by fire. In the first stage, the temperature rises steadily over time, in minutes to 10s minutes. In this phase, in an example implementation, the subject-cell measured temperature is compared with an estimated cell temperature. When the measured value exceeds a pre-defined threshold, the DX cooling system 1090 is controlled to go in an emergency-thermal-boost mode. In this mode, the control parameters of DX cooling system 1090 are set to drive evaporator's segment temperature (of the evaporation system 1006) around the subject-location to a very low value. The subject location temperature is driven to −20 degrees C. (in an example implementation), increasing the heat extraction capability of evaporator segment multi-fold.

In another example implementation, the controls system performs a partial or complete shutdown of the electrical power flow, which stops any further increase in heat load (by the battery pack 1001 and PETC system 1002) from the healthy evaporator segment of the evaporation system 1006, freeing up the compressors of the compression system 1003 to operate in group mode to increase the heat extraction from a target evaporator segment of the evaporation system 1006 where the subject-cell is located. The subject-cell prior to the onset of thermal runaway continues to release more heat despite electrical isolation due to internal cell failure. However, due to the group operation of compressors, the heat extraction capacity is now a lot more, resulting in decreasing and eventually pulling the subject cell's temperature to a safe level to stop the onset of thermal runaway. The controls system to control processes described herein is included in the universal battery module 1000 in an example implementation.

Depending on the cell's technology, the evaporator temperature is set to practically freeze the subject-cell and the cells in the segment of the subject-cell-location. So, not only the subject cell but the cell string for example in that segment of evaporator is driven toward a freezing temperature at which the cells becomes practically useless and the internal chain reaction of increase in heat generation stops, thereby stopping the events completely and thus eliminating the chances of thermal runaway.

The subject-universal-module is controlled to get back to the normal operations by isolating the cell string that contains the subject-cell, which can be achieved by disabling the respective PETCM, and utilizing the thermal isolation barriers between the different segments of the evaporator segments. Note, during this entire emergency-thermal-boost operation, other universal modules are under normal operations, fully isolated, both electrically and thermally, from abnormal events in the subject-universal-module.

In another example implementation, the emergency-thermal-boost is enabled by sensing the composition of gas inside the universal module.

In yet another example, a combination of sensing temperature, gas, and voltage can be used to trigger emergency-thermal-boost mode.

In another example, an RFID tag is used with the string of cells to detect the location which is used to identify the subject-cell-location.

In another example implementation, the DX cooling system can be used to heat the battery pack and the PETC system.

To protect the system from shock and vibration and possible crashes, which could be possible if the BESS is used as a portable BESS, the BESS includes a shock and vibration sensor that is used to trigger the emergency-thermal-boost mode.

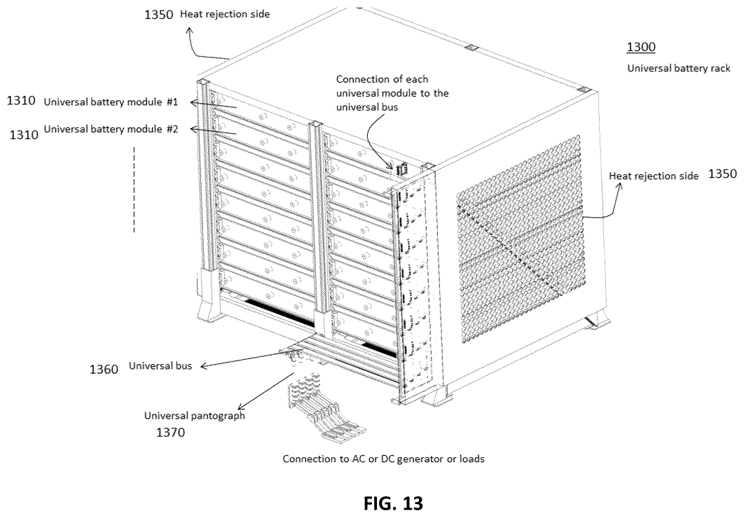

FIG. 13 shows an example implementation of the universal battery rack 1300. Several universal battery module 1310 are installed in a ruggedized frame such that the heat rejection system (condenser sets) of the DX cooling system faces outside (shown as 1350) for heat rejection to the atmosphere. The universal battery module 1310 are connected in parallel to the universal bus 1360 is shown. Each universal battery module in this example is a 100 to 150 kWh energy rating and a power rating of approximately 75 kW ac or dc, resulting in a total rating of the universal battery rack 1300 to be ˜500 kW and 1 MWh, which fits in ˜8 ft×8 ft×6 ft space. The universal pantograph 1370 for AC or DC connection to the utility power system or DC power system is also shown.

For comparison, the state-of-the-art 500 kW 1 MWh BESS capable of interfacing with both an AC and DC power system directly and including the thermal management system will have a significantly larger form factor and weight. This implementation reduces the overall system footprint and substantially reduces the BESS's installed cost. It is particularly useful for a portable BESS where shipping costs are inversely proportional to the power and energy density.

While the invention has been described in conjunction with the specific embodiments described herein, it is evident that many alternatives, combinations, modifications and variations are apparent to those skilled in the art. Accordingly, the example embodiments of the invention, as set forth herein are intended to be illustrative only, and not in a limiting sense. Various changes can be made without departing from the spirit and scope of the invention.

What is claimed is:

1. A system, comprising:
a universal bus; and
universal battery modules connected to the universal bus and in parallel, and at least one of the modules, comprising:
battery cells;
a power electronics transformer converter (PETC) system comprising multiple input and output terminals, wherein the input terminals are galvanically isolated from one another and galvanically isolated from the output terminals, and wherein the galvanic isolation is at least provided by transformers; and
a direct expansion (DX) based phase-change cooling system that is installed near the battery pack and PETC system.

2. The system of claim 1, wherein the universal bus comprises an alternating current (AC) bus and the system is connected to an AC generator or load.

3. The system of claim 1, wherein at least one of the output terminals of the PETC system includes a three-phase AC output terminal.

4. The system of claim 1, wherein the universal bus comprises a direct current (DC) bus and the system is connected to a DC generator or load, and wherein each PETC system is configured to comprise DC/DC converters.

5. The system of claim 1, wherein the system, via the universal bus and a switch network, interfaces directly with a DC generator or load and an AC generator or load, and wherein the switch network is configured to switch between active couplings with the DC generator or load and the AC generator or load.

6. The system of claim 4, wherein each PETC system is configured to include universal converters and wherein the output terminals are a three-phase AC or high voltage DC for charging and discharging the battery cells.

7. The system of claim 1, wherein universal battery module does not have any parallel connection of battery cells or any parallel connection of string of battery cells.

8. A power electronics transformer converter (PETC) system, comprising:
power electronics; and
multiple power electronics transformer modules (PETCMs), each one of the PETCMs connected in parallel at its output terminals and comprising:
a part of the power electronics and high-frequency transformers to provide galvanic isolation among its input terminals and its outputs terminals and to provide power conversion for charging and discharging battery cells; and
an integrated switching network that converts an output terminal to an AC output or DC output terminal depending on a state of a switch inside the switching network, wherein the state of the switch is controlled to configure an output terminal as DC or AC.

9. The PETC system of claim 8, wherein the PETC system comprises a single-phase alternating current (AC) output interface or a direct current (DC) output interface to a universal bus, and wherein the system switches between interfaces via a switch.

10. The PETC system of claim 8, comprising a three-phase AC output interface or multiple-DC output interface with a universal bus, and wherein the switching network comprises a group of three switches.

11. A system, comprising:
at least one universal battery module;
at least one universal bus; and
at least one direct expansion (DX) based thermal management system integrated with components of the universal battery module, wherein the DX system comprises an expansion system, a compression system, a condenser system, and an evaporation system.

12. The system of claim 11, wherein the evaporation system comprises at least one cold plate configured to hold a battery pack and at least part of the module.

13. The system of claim 12, wherein the cold plate comprises channels for coolant flow and wherein sensors integrated with the components of the universal battery modules to identify a location of subject cell on a onset of thermal runaway.

14. The system of claim 11, wherein multiple universal modules are mounted to a frame such that a heat rejection system is integrated with the modules and the condenser sets of the module face outward from the frame for expelling heat produced by the modules, and wherein the modules are connected in parallel and with at least one universal bus.

15. The system of claim 14, wherein the heat rejection system comprises a cold plate configured to hold a battery pack and at least part of a universal battery module, and wherein the cold plate comprises channels for coolant flow.

16. The system of claim 14, wherein at least one universal pantograph is coupled to at least one universal bus and wherein said universal pantograph is reconfigurable to connect to AC power system at one time and to DC power system at another time.

17. The system of claim 14, wherein at least one universal pantograph is coupled to at least one universal bus.

18. The system of claim 17, wherein said universal pantograph is reconfigurable to connect to AC power system at one location and a DC power system at another location.

19. The system of claim 14, wherein at least one sensor is attached to the frame for stopping electrical charging or discharging of at least one universal battery module.

20. The system of claim 14, wherein multiple universal battery modules and at least one universal pantograph are coupled to a control system for managing a reconfiguration operation to connect to an AC or DC power system.
